(19) United States
(12) Patent Application Publication
(10) Pub. No.: US 2026/0334007 A1
(43) Pub. Date: Oct. 22, 2026

(54) ARRAY SUBSTRATE, DISPLAY PANEL, AND DISPLAY DEVICE

(71) Applicant: Yungu (Gu’an) Technology Co., Ltd., Langfang (CN)

(72) Inventors: Lei MI, Langfang (CN); Cuili GAI, Langfang (CN); Feng ZHANG, Langfang (CN)

(73) Assignee: Yungu (Gu’an) Technology Co., Ltd., Langfang (CN)

(21) Appl. No.: 19/711,873

(22) Filed: Jun. 17, 2026

(30) Foreign Application Priority Data
Aug. 13, 2025 (CN) 202511135045.4

(51) Int. Cl. H10K 59/121; H10D 86/40; H10D 86/60; H10H 29/32; H10H 29/49; H10K 59/131

(52) U.S. Cl. CPC H10K 59/1213; H10D 86/423; H10D 86/441; H10D 86/60; H10H 29/32; H10H 29/49; H10K 59/1216; H10K 59/131

(57) ABSTRACT

The present application discloses an array substrate, a display panel, and a display device. The array substrate includes a substrate and a plurality of pixel circuits on the substrate. A pixel circuit includes a first transistor and a first capacitor. The first transistor includes a first gate and a first channel region. A first plate of the first capacitor is on one side of the first transistor and electrically connected to a first electrode of the first transistor, and the first gate serves as a second plate of the first capacitor. Orthographic projections of the first gate and the first channel region on the substrate have a first overlapping portion; orthographic projections of the first plate and the second plate on the substrate have a second overlapping portion; and the first overlapping portion overlaps the second overlapping portion. The performance of a display product can thereby be improved.

### CROSS-REFERENCE TO RELATED APPLICATIONS

This application claims priority to Chinese Patent Application No. 202511135045.4, filed on Aug. 13, 2025, entitled “ARRAY SUBSTRATE, DISPLAY PANEL, AND DISPLAY DEVICE”, the entire contents of which are incorporated herein by reference.

### FIELD

The present application relates to the field of display technology, and specifically to an array substrate, a display panel, and a display device.

### BACKGROUND

Organic Light Emitting Diode (OLED) and Light Emitting Diode (LED)-based flat display devices are widely used in various consumer electronic products such as mobile phones, televisions, notebook computers, and desktop computers due to their advantages of high image quality, low power consumption, thin form factor, and wide application range, becoming mainstream in display devices. However, the performance of current OLED display products needs improvement.

### SUMMARY

Embodiments of the present application provide an array substrate, a display panel, and a display device, which can improve the performance of display products.

An embodiment of the present application provides an array substrate, including a substrate and a plurality of pixel circuits disposed on one side of the substrate. The pixel circuit includes: a first transistor and a first capacitor, the first transistor including a first gate and a first channel region; a first plate of the first capacitor is disposed on one side of the first transistor and electrically connected to a first electrode of the first transistor, the first gate serving as a second plate of the first capacitor; and an orthographic projection of the first gate on the substrate and an orthographic projection of the first channel region on the substrate have a first overlapping portion, an orthographic projection of the first plate of the first capacitor on the substrate and an orthographic projection of the second plate of the first capacitor on the substrate have a second overlapping portion, and the first overlapping portion and the second overlapping portion overlap.

In one embodiment of the present application, the pixel circuit further includes: a second transistor and a second capacitor, the second transistor is disposed on a side of the first capacitor away from the first transistor, a first electrode of the second transistor is electrically connected to the first gate; the first plate of the first capacitor serves as a first plate of the second capacitor, a second plate of the second capacitor is disposed between the second transistor and the first plate of the first capacitor, and the second plate of the second capacitor is configured to be supplied with a fixed voltage.

In one embodiment of the present application, an orthographic projection of the first plate of the second capacitor on the substrate and an orthographic projection of the second plate of the second capacitor on the substrate have a third overlapping portion, and the third overlapping portion and the first overlapping portion overlap.

In one embodiment of the present application, the first overlapping portion, the second overlapping portion, and the third overlapping portion all overlap.

In one embodiment of the present application, the first overlapping portion is located within the third overlapping portion.

In one embodiment of the present application, the first overlapping portion is located within the third overlapping portion, and the first overlapping portion is located within the second overlapping portion.

In one embodiment of the present application, the second transistor includes a second gate and a second channel region, an orthographic projection of the second gate on the substrate and an orthographic projection of the second channel region on the substrate have a fourth overlapping portion, and the fourth overlapping portion overlaps with the second overlapping portion, and the fourth overlapping portion overlaps with the third overlapping portion.

In one embodiment of the present application, the fourth overlapping portion, the second overlapping portion, and the third overlapping portion all overlap.

In one embodiment of the present application, the first overlapping portion is located within the second overlapping portion.

In one embodiment of the present application, the pixel circuit further includes a second transistor disposed on a side of the first capacitor away from the first transistor, a first electrode of the second transistor is electrically connected to the first gate. The second transistor includes a second gate and a second channel region, an orthographic projection of the second gate on the substrate and an orthographic projection of the second channel region on the substrate have a fourth overlapping portion, and the fourth overlapping portion and the first overlapping portion do not overlap.

In one embodiment of the present application, the first transistor includes a first active structure, the first channel region is located in the first active structure, and: the first plate of the first capacitor is disposed on a side of the first gate away from the first active structure.

In one embodiment of the present application, the pixel circuit further includes a first via, the first electrode of the second transistor is electrically connected to the first gate through the first via, and an orthographic projection of the first via on the substrate is located outside the first overlapping portion.

In one embodiment of the present application, the second transistor includes a second active structure and a second gate disposed in different layers, the second channel region of the second transistor is located in the second active structure, a first doped region of the second active structure is disposed on one side of the second channel region and serves as the first electrode of the second transistor, and a second doped region of the second active structure is disposed on a side of the second channel region away from the first doped region and serves as a second electrode of the second transistor.

In one embodiment of the present application, the pixel circuit further includes a second via, the array substrate further includes: a plurality of first signal lines, the plurality of first signal lines are disposed on a side of the second transistor facing the first transistor, and the second electrode of the second transistor is electrically connected to a corresponding first signal line through the second via.

In one embodiment of the present application, a film layer where the plurality of first signal lines are located is between a film layer where the second plate of the second capacitor is located and a film layer where the second gate of the second transistor is located, or, the film layer where the plurality of first signal lines are located is the same film layer as the film layer where the second plate of the second capacitor is located.

In one embodiment of the present application, the pixel circuit further includes a third via and a fourth via, the array substrate further includes a plurality of second signal lines, and: a first doped region of the first active structure and a second doped region of the first active structure are located on two sides of the first channel region, the first doped region of the first active structure serves as the first electrode of the first transistor, and the second doped region of the first active structure serves as a second electrode of the first transistor; the first electrode of the first transistor is electrically connected to the first plate of the first capacitor through the third via, and the second electrode of the first transistor is electrically connected to a corresponding second signal line through the fourth via.

In one embodiment of the present application, the pixel circuit further includes a transfer portion, the transfer portion is located on a side of the first active structure away from the first gate, and the transfer portion is electrically connected to the first electrode of the first transistor and the first plate of the first capacitor through the third via.

In one embodiment of the present application, a film layer where the plurality of second signal lines are located is the same film layer as a film layer where the transfer portion is located, or, the film layer where the plurality of second signal lines are located is on a side of the film layer where the transfer portion is located away from the film layer where the first active structure is located.

In one embodiment of the present application, the material of the first active structure includes indium gallium zinc oxide, and the material of the second active structure includes polysilicon. In one embodiment of the present application, the first transistor is located on a side of the second transistor away from the substrate. In one embodiment of the present application, the first signal line is a data line, and the second signal line is a first power supply line. In one embodiment of the present application, the first transistor is a driving transistor, and the second transistor is a switching transistor. In one embodiment of the present application, a plurality of pixel circuits are arranged along a first direction and a second direction. A plurality of first gates of the plurality of pixel circuits are spaced apart from each other, the first gates extend along the second direction, a plurality of second gates of the plurality of pixel circuits arranged along the first direction are of an integral structure, and a plurality of second gates of the plurality of pixel circuits arranged along the second direction are spaced apart from each other. In one embodiment of the present application, a plurality of first plates of a plurality of first capacitors of the plurality of pixel circuits are spaced apart from each other, and the first plates of the first capacitors extend along the second direction. In one embodiment of the present application, an orthographic projection of the first gate on the substrate includes a first portion, the first portion is located outside an orthographic projection of the corresponding first plate of the first capacitor on the substrate, the orthographic projection of the first plate of the first capacitor on the substrate includes a second portion, and the second portion is located outside the orthographic projection of the corresponding first gate on the substrate. In one embodiment of the present application, the corresponding first portion, first overlapping portion, and second portion are arranged along the second direction. In one embodiment of the present application, a plurality of second plates of a plurality of second capacitors of the plurality of pixel circuits arranged along the first direction are of an integral structure, and a plurality of second plates of a plurality of second capacitors of the plurality of pixel circuits arranged along the second direction are spaced apart from each other. In one embodiment of the present application, the array substrate further includes a plurality of first signal lines, the first signal lines extend along the second direction, second electrodes of a plurality of second transistors of the plurality of pixel circuits arranged along the second direction are electrically connected to the same first signal line, and second electrodes of a plurality of second transistors of the plurality of pixel circuits arranged along the first direction are electrically connected to different first signal lines. In one embodiment of the present application, the array substrate further includes a plurality of second signal lines, the second signal lines extend along the first direction, second electrodes of a plurality of first transistors of the plurality of pixel circuits arranged along the first direction are electrically connected to the same second signal line, and second electrodes of a plurality of first transistors of the plurality of pixel circuits arranged along the second direction are electrically connected to different second signal lines. In one embodiment of the present application, the pixel circuit further includes a transfer portion, the transfer portion is electrically connected to a first electrode of the first transistor, a plurality of transfer portions of the plurality of pixel circuits are spaced apart from each other, and the transfer portions extend along the second direction. In one embodiment of the present application, the array substrate further includes a plurality of first electrodes, the plurality of first electrodes are located on a side of the plurality of pixel circuits away from the substrate, and an orthographic projection of the first electrode on the substrate overlaps with the first overlapping portion. In one embodiment of the present application, the first overlapping portion is located within the orthographic projection of the first electrode on the substrate. An embodiment of the present application further provides a display panel, including a display area and a frame area, the display panel including: a first power supply line and the array substrate according to any one of the embodiments. The first power supply line is at least located in the frame area and is configured to supply a first power supply voltage. A plurality of pixel circuits are located in the display area and are arranged along a first direction and a second direction. The array substrate further includes a plurality of second signal lines, the second signal lines are electrically connected to second electrodes of corresponding first transistors. The second signal lines extend along the first direction and are electrically connected to the first power supply line in the frame area. In some embodiments of the second aspect, the pixel circuit further includes: a second transistor and a second capacitor, the second transistor is disposed on a side of the first capacitor away from the first transistor, a first electrode of the second transistor is electrically connected to the first gate. The first plate of the first capacitor serves as a first plate of the second capacitor, and a second plate of the second capacitor is disposed between the second transistor and the first plate of the first capacitor and is configured to receive a fixed voltage. A plurality of second plates of a plurality of second capacitors of the plurality of pixel circuits arranged along the first direction are of an integral structure and are electrically connected to corresponding signal lines in the frame area, and a plurality of second plates of a plurality of second capacitors of the plurality of pixel circuits arranged along the second direction are spaced apart from each other. In one embodiment of the present application, a plurality of second plates of a plurality of second capacitors of the plurality of pixel circuits arranged along the first direction are of an integral structure and are electrically connected to the first power supply line in the frame area. An embodiment of the present application further provides a display device, including: a driving chip and the display panel according to the embodiment of the second aspect. The driving chip is configured to provide a data voltage; and the pixel circuit further includes a second transistor, disposed on a side of the first capacitor away from the first transistor, a first electrode of the second transistor is electrically connected to the first gate, the array substrate further includes a plurality of first signal lines, the first signal lines extend along the second direction and are electrically connected to the driving chip in the frame area, and the first signal lines are electrically connected to second electrodes of corresponding second transistors. According to the array substrate, display panel, and display device provided by the embodiments of the present application, the first plate is reused as a third plate, and one metal block serves as two plates of two capacitors, which can reduce the area occupied by the two capacitors, thereby facilitating an increase in pixels per inch (PPI). The first channel region of the first transistor is separated from the vertical projection of the second transistor on the substrate, which is beneficial for the flatness of the effective channel of the first transistor, thereby ensuring the performance of the first transistor. In one embodiment, the improvement in display quality of the display product can be ensured while enhancing the PPI.

According to the array substrate, display panel, and display device provided in the embodiments of the present application, compared to the need for separate metal blocks for both the first gate electrode and the second plate of the first capacitor, in this embodiment, the first gate electrode and the second plate of the first capacitor are multiplexed. Thus, the same metal block serves as two structures, reducing the area occupied by the pixel circuit, thereby facilitating an increase in PPI. The first overlapping portion and the second overlapping portion at least partially overlap each other. Consequently, within at least a part of the overlapping region between the first gate electrode of the first transistor and the first channel region of the first transistor, the first plate and the second plate of the first capacitor can be disposed. This maximizes the overlapping area of the two plates of the first capacitor, thereby achieving maximization of the first capacitor to improve circuit reliability. The above description is an overview of the embodiments of the present application. To provide a clearer understanding of the technical means of the present application, it can be implemented in accordance with the contents of the specification. To make the above and other purposes, features, and advantages of the present application more apparent and understandable, specific embodiments of the present application are exemplified below.

### BRIEF DESCRIPTION OF THE DRAWINGS

Other features, purposes, and advantages of the present application will become more apparent upon reading the detailed description of non-limiting embodiments with reference to the accompanying drawings, and identical or similar reference numerals denote identical or similar features, and the drawings are not drawn to actual scale.

FIG. 1 shows a schematic diagram of a film layer stacking structure of an array substrate provided in an embodiment of the present application;

FIG. 2 shows a schematic diagram of a structure of a pixel circuit in the array substrate provided in an embodiment of the present application;

FIG. 3 shows a schematic diagram of another film layer stacking structure of the array substrate provided in an embodiment of the present application;

FIG. 4 shows a schematic diagram of yet another film layer stacking structure of the array substrate provided in an embodiment of the present application;

FIG. 5 shows a schematic diagram of a process flow corresponding to FIG. 1;

FIG. 6 shows a schematic diagram of a process flow corresponding to FIG. 3;

FIG. 7 shows a schematic diagram of a process flow corresponding to FIG. 4;

FIGS. 8 to 16 show schematic top-view structural diagrams of a local region of the array substrate provided in embodiments of the present application;

FIG. 17 shows a schematic diagram of a structure of a display panel provided in an embodiment of the present application;

FIG. 18 shows a schematic diagram of a structure of a display device provided in an embodiment of the present application.

### DETAILED DESCRIPTION OF THE EMBODIMENTS

Features and exemplary embodiments of various aspects of the present application will be described below. To make the purpose, embodiments, and advantages of the present application clearer, the present application is further described below in conjunction with the accompanying drawings and specific embodiments. The specific embodiments described herein are configured to explain the present application and are not configured to limit the present application. The present application can be implemented without some of these specific details. The description of the embodiments below is to provide a better understanding of the present application by illustrating examples of the present application.

Before elaborating on the embodiments provided in the embodiments of the present application, to facilitate understanding of the embodiments of the present application, the present application first explains problems existing in related art:

As a carrier for information display and a window for human-computer interaction in the digital age, display screens have become an important port for people to receive visual information, continuously influencing people's lives and economic and social development. With technological progress and the continuous improvement of people's information interaction needs, commercial displays are integrating into life at an unprecedented speed. For example, various forms of commercial display screens are integrated with the environment and applied in functions such as Augmented Reality (AR), Virtual Reality (VR), and holographic projection.

However, current OLED displays perform poorly in the AR/VR field because, limited by array and OLED process capabilities, they cannot achieve high pixel density (PPI).

The embodiments of the present application provide an array substrate, a display panel, and a display device. Various embodiments of the present application will be described below in conjunction with the accompanying drawings.

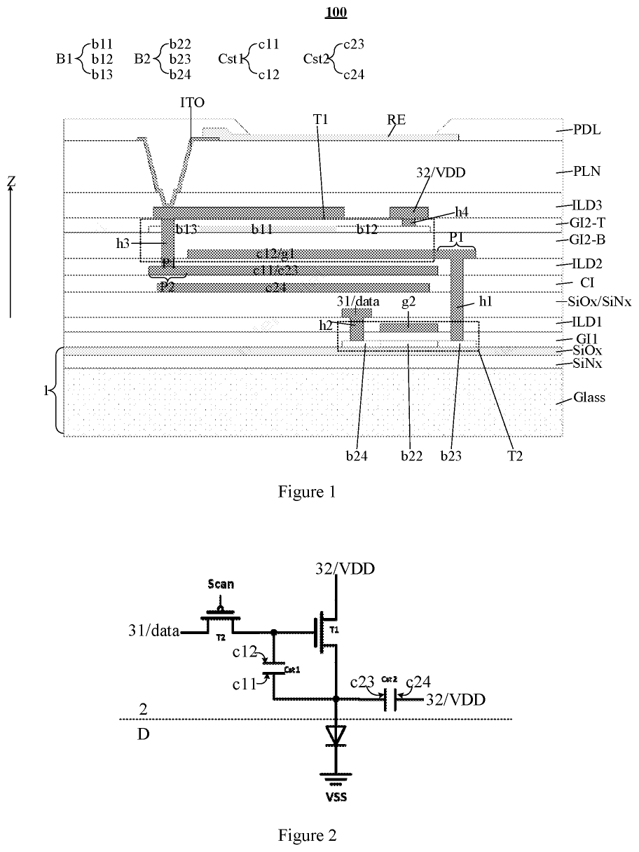

As shown in FIG. 1 and FIG. 2, the array substrate 100 provided in the embodiment of the present application includes a substrate 1 and a plurality of pixel circuits 2 disposed on one side of the substrate 1.

The pixel circuit 2 is used to drive a light-emitting element D, and the pixel circuit 2 at least includes a first transistor T1 and a first capacitor Cst1.

The first transistor T1 includes a first gate electrode g1 and a first channel region b11. The first capacitor Cst1 includes a first plate c11 and a second plate c12.

The first plate c11 of the first capacitor Cst1 is disposed on one side of the first transistor T1, and the first plate c11 of the first capacitor Cst1 is electrically connected to a first electrode of the first transistor. The first gate electrode g1 serves as the second plate c12 of the first capacitor Cst1.

The first gate electrode g1 is multiplexed with the second plate c12 of the first capacitor Cst1, that is, the first gate electrode g1 and the second plate c12 of the first capacitor Cst1 in the same pixel circuit 2 are the same metal block, which serves both as the first gate electrode g1 of the first transistor T1 and as the second plate c12 of the first capacitor Cst1.

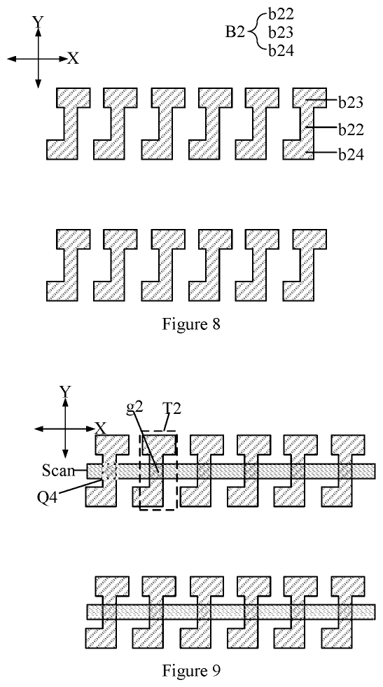

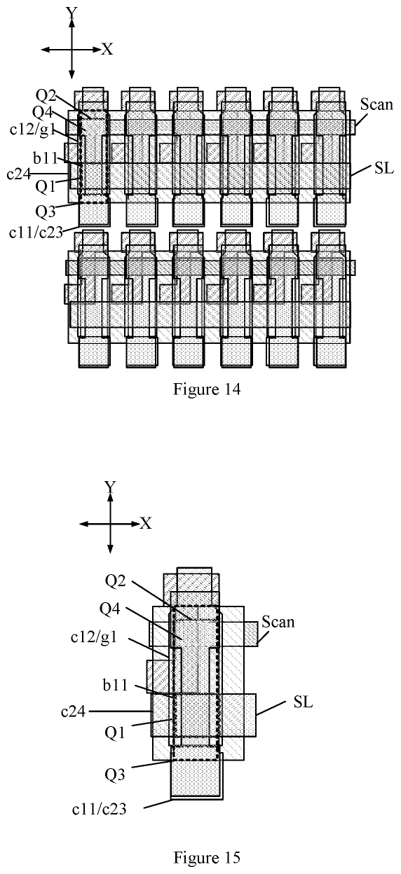

FIGS. 8 to 16 show some schematic top-view structural diagrams of the array substrate provided in the embodiments of the present application, and structures filled with the same color pattern represent structures located in the same film layer, and structures filled with different color patterns represent structures located in different film layers. FIG. 14 and FIG. 15, in one embodiment, show the pattern structures of the film layers where the first active structure of the first transistor, the first plate c11, the second plate c12 of the first capacitor Cst, and other device structures are located. FIG. 15 is an enlarged schematic diagram of a region where one pixel circuit is located in FIG. 14. FIG. 14 and FIG. 15 also show a shielding injection layer SL, which is used to define the first channel region of the first transistor T1, and the shielding injection layer SL may not be included in the array substrate as shipped. The pattern structures shown in FIGS. 8 to 16 are examples and are not intended to limit the present application.

Referring to FIGS. 1, 14, and 15, the orthographic projection of the first gate g1 of the first transistor T1 on the substrate and the orthographic projection of the first channel region b11 of the first transistor T1 on the substrate have a first overlapping portion Q1. The orthographic projection of the first plate c11 of the first capacitor Cst1 on the substrate and the orthographic projection of the second plate c12 of the first capacitor Cst1 on the substrate have a second overlapping portion Q2. The first overlapping portion Q1 and the second overlapping portion Q2 at least partially overlap.

The orthographic projections of the first gate g1 of the first transistor T1, the first channel region b11 of the first transistor T1, the first plate c11 of the first capacitor Cst1, and the second plate c12 of the first capacitor Cst1 on the substrate at least partially overlap. In at least a part of the overlapping region of the first gate g1 of the first transistor T1 and the first channel region b11 of the first transistor T1, the first plate c11 of the first capacitor Cst1 and the second plate c12 of the first capacitor Cst1 may be disposed. Thus, the overlapping area of the two plates of the first capacitor Cst1 can be maximized, thereby achieving maximization of the first capacitor Cst1.

To clearly illustrate different overlapping portions, in the drawings of the present application, different overlapping portions are indicated by dashed boxes of different colors. A red dashed box indicates the first overlapping portion Q1, a purple dashed box indicates the second overlapping portion Q2, a black dashed box indicates the third overlapping portion Q3, and a yellow dashed box indicates the fourth overlapping portion Q4. The third overlapping portion Q3 and the fourth overlapping portion Q4 will be described later.

According to the array substrate provided by the embodiment of the present application, compared to the case where both the first gate g1 and the second plate c12 of the first capacitor Cst1 require separate metal blocks, in this embodiment, the first gate g1 and the second plate c12 of the first capacitor Cst1 are reused. Thus, the same metal block serves as two structures, which can reduce the area occupied by the pixel circuit, thereby facilitating an increase in PPI. The first overlapping portion Q1 and the second overlapping portion Q2 at least partially overlap. Accordingly, in at least a part of the overlapping region of the first gate g1 of the first transistor T1 and the first channel region b11 of the first transistor T1, the first plate c11 of the first capacitor Cst1 and the second plate c12 of the first capacitor Cst1 may be disposed. Therefore, the overlapping area of the two plates of the first capacitor Cst1 can be maximized, thereby achieving maximization of the first capacitor Cst1 to improve circuit reliability.

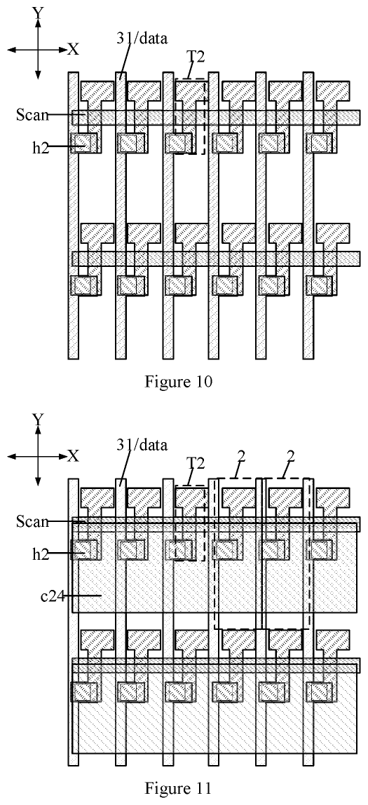

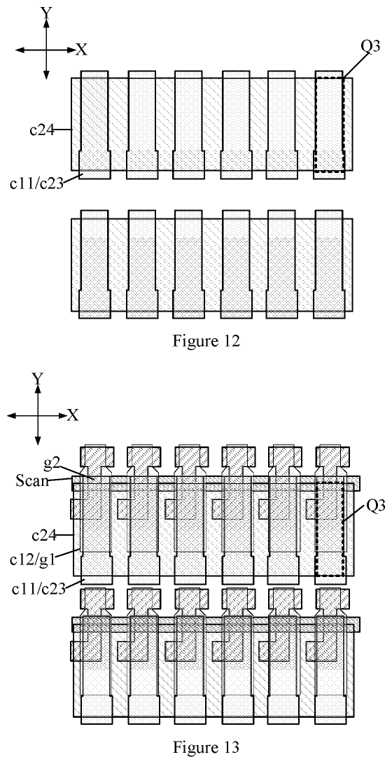

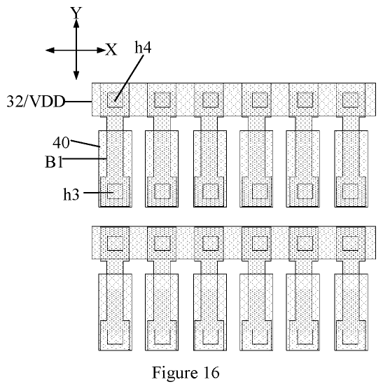

In some embodiments, as shown in FIGS. 1 and 2, the pixel circuit 2 further includes a second transistor T2 and a second capacitor Cst2. Exemplarily, the second transistor T2 includes a second active structure B2. FIG. 8, in one embodiment, shows the pattern structure of the film layer where the second active structure of the second transistor is located. FIG. 9, in one embodiment, shows the pattern structure of the film layer where the second active structure and the scan line Scan are located. FIG. 10, in one embodiment, shows the pattern structure of the film layer where the second active structure, the scan line Scan, and the first signal line 31 are located. FIG. 11, in one embodiment, shows the pattern structure of the film layer where the second active structure, the scan line Scan, the first signal line 31, and the second plate c24 of the second capacitor are located. FIG. 12, in one embodiment, shows the pattern structure of the film layer where the first plate c23 and the second plate c24 of the second capacitor are located. FIG. 13, in one embodiment, shows the pattern structure of the film layer where the second active structure of the second transistor, the scan line Scan, the first plate c23 and the second plate c24 of the second capacitor, and the second plate c12 of the first capacitor are located. FIG. 16, in one embodiment, shows the pattern structure of the film layer where the first active structure of the first transistor and the second signal line are located.

The second transistor T2 is disposed on a side of the first capacitor Cst1 away from the first transistor T1. A first electrode of the second transistor T2 is electrically connected to the first gate g1 of the first transistor T1. In the thickness direction Z of the array substrate, the second transistor T2 is located on a side of the first capacitor Cst1 away from the first transistor T1. The first transistor T1 and the second transistor T2 are located in different film layers and are stacked in the thickness direction Z of the array substrate.

The first plate c11 of the first capacitor Cst1 serves as the first plate c23 of the second capacitor Cst2. The second plate c24 of the second capacitor Cst2 is disposed between the second transistor T2 and the first plate c11 of the first capacitor Cst1. The second plate c24 of the second capacitor Cst2 is configured to receive a fixed voltage.

The first plate c11 of the first capacitor Cst1 is reused as the first plate c23 of the second capacitor Cst2. The second plate c12 of the first capacitor Cst1 and the second plate c24 of the second capacitor Cst2 are connected to different signal traces.

Since the first plate c11 of the first capacitor Cst1 and the first plate c23 of the second capacitor Cst2 are reused, in the same pixel circuit, the first plate c11 of the first capacitor Cst1 and the first plate c23 of the second capacitor Cst2 are the same metal block. This metal block serves both as the first plate c11 of the first capacitor Cst1 and as the first plate c23 of the second capacitor Cst2. In an equivalent circuit diagram of the pixel circuit, the first plate c11 of the first capacitor Cst1 and the first plate c23 of the second capacitor Cst2 are connected to the same node. The second plate c12 of the first capacitor Cst1 and the second plate c24 of the second capacitor Cst2 are connected to different nodes.

Compared to the case where both plates of the first capacitor Cst1 and both plates of the second capacitor Cst2 need to be separately fabricated, in this embodiment, the first plate c11 of the first capacitor Cst1 is reused as the first plate c23 of the second capacitor Cst2. Thus, one metal block serves as two plates of two capacitors, which can reduce the area occupied by the two capacitors, thereby facilitating an increase in PPI.

As an example, the second gate of the second transistor T2 is electrically connected to the scan line Scan, the first electrode of the second transistor T2 is electrically connected to the gate of the first transistor T1, and the second electrode of the second transistor T2 is electrically connected to the first signal line 31. The first electrode of the first transistor T1 is electrically connected to the second signal line 32, and the second electrode of the first transistor T1 is electrically connected to the first electrode of the light-emitting element D. The second electrode of the light-emitting element D is electrically connected to the common signal line VSS. The first electrode plate c11 of the first capacitor Cst1 is electrically connected to the first electrode of the light-emitting element D, and the second electrode plate c12 of the first capacitor Cst1 is electrically connected to the gate of the first transistor T1. The first electrode plate c23 of the second capacitor Cst2 is electrically connected to the first electrode of the light-emitting element D, and the second electrode plate c24 of the second capacitor Cst2 is electrically connected to the second signal line 32.

The first signal line 31 includes a data signal line data, and the second signal line 32 includes a positive power supply signal line VDD.

The pixel circuit shown in FIG. 2 is an example, and this is not intended to limit the present application. The present application may also be applicable to pixel circuits of other structures than the pixel circuit shown in FIG. 2.

Exemplarily, the first transistor T1 may serve as a driving transistor, and the second transistor T2 may serve as a switching transistor. The first transistor T1 is used to generate a driving current to drive the light-emitting element to emit light.

The first transistor T1 includes an oxide transistor, and the second transistor T2 includes a low-temperature polysilicon transistor. In one embodiment of the present application, the first transistor T1 includes indium gallium zinc oxide (IGZO), and the second transistor T2 includes low-temperature poly-silicon (LTPS).

In some embodiments, with reference to FIG. 1, FIG. 12, and FIG. 13, an orthographic projection of the first electrode plate c23 of the second capacitor Cst2 on the substrate 1 and an orthographic projection of the second electrode plate c24 of the second capacitor Cst2 on the substrate 1 have a third overlapping portion Q3.

Referring to FIG. 14 or FIG. 15, the third overlapping portion Q3 and the first overlapping portion Q1 at least partially overlap.

In at least a portion of an overlapping region of the first gate g1 of the first transistor T1 and the first channel region b11 of the first transistor T1, the orthographic projection of the first electrode plate c23 of the second capacitor Cst2 on the substrate 1 and the second electrode plate c24 of the second capacitor Cst2 may be disposed. In one embodiment, the overlapping area of the two electrode plates of the second capacitor Cst2 can be maximized, thereby achieving maximization of the second capacitor Cst2.

In some embodiments, as shown in FIG. 14 or FIG. 15, the first overlapping portion Q1, the second overlapping portion Q2, and the third overlapping portion Q3 at least partially overlap. In at least a portion of an overlapping region of the first gate g1 of the first transistor T1 and the first channel region b11 of the first transistor T1, the first electrode plate c11 of the first capacitor Cst1 and the second electrode plate c12 of the first capacitor Cst1 may be disposed, and the orthographic projection of the first electrode plate c23 of the second capacitor Cst2 on the substrate 1 and the second electrode plate c24 of the second capacitor Cst2 may also be disposed. In one embodiment, while minimizing the area occupied by the pixel circuit, the overlapping area of the two electrode plates of the first capacitor Cst1 and the overlapping area of the two electrode plates of the second capacitor Cst2 can be maximized, thereby achieving maximization of the first capacitor Cst1 and maximization of the second capacitor Cst2.

In some embodiments, as shown in FIG. 14 or FIG. 15, the first overlapping portion Q1 is located within the third overlapping portion Q3. The third overlapping portion Q3 is a portion where the first electrode plate c23 and the second electrode plate c24 of the second capacitor Cst2 overlap, the area of the third overlapping portion Q3 is larger than the area of the first overlapping portion Q1, and the region where the third overlapping portion Q3 is located includes the first overlapping portion Q1. In one embodiment, it is more advantageous to achieve maximization of the second capacitor Cst2 while minimizing the area occupied by the pixel circuit.

In some embodiments, as shown in FIG. 14 or FIG. 15, the first overlapping portion Q1 is located within the third overlapping portion Q3, and the first overlapping portion Q1 is located within the second overlapping portion Q2. In this example, the area of the third overlapping portion Q3 is larger than the area of the first overlapping portion Q1, and the area of the second overlapping portion Q2 is larger than the area of the first overlapping portion Q1. The region where the third overlapping portion Q3 is located includes the first overlapping portion Q1, and the region where the second overlapping portion Q2 is located includes the first overlapping portion Q1. In one embodiment, it is more advantageous to achieve maximization of the first capacitor Cst1 and the second capacitor Cst2 while minimizing the area occupied by the pixel circuit.

In some embodiments, with reference to FIG. 1, FIG. 14, and FIG. 15, the second transistor T2 includes a second gate g2 and a second channel region b22, and an orthographic projection of the second gate g2 on the substrate 1 and an orthographic projection of the second channel region b22 on the substrate 1 have a fourth overlapping portion Q4. The fourth overlapping portion Q4 overlaps with the second overlapping portion Q2. The fourth overlapping portion Q4 overlaps with the third overlapping portion Q3. In this example, the second transistor T2 at least partially overlaps with the first capacitor Cst1. The second transistor T2 at least partially overlaps with the second capacitor Cst2. In one embodiment, more devices can be disposed within a limited area, thereby optimizing the performance of the pixel circuit and achieving maximization of the capacitors.

In some embodiments, the fourth overlapping portion Q4, the second overlapping portion Q2, and the third overlapping portion Q3 overlap. In one embodiment, while minimizing the area occupied by the pixel circuit, the overlapping area of the two electrode plates of the first capacitor Cst1 and the overlapping area of the two electrode plates of the second capacitor Cst2 can be maximized, thereby achieving maximization of the first capacitor Cst1 and maximization of the second capacitor Cst2.

In some embodiments, as shown in FIG. 1, FIG. 14, or FIG. 15, the first overlapping portion Q1 is located within the second overlapping portion Q2. The pixel circuit further includes a second transistor T2, which is disposed on a side of the first capacitor Cst1 away from the first transistor T1. A first electrode of the second transistor T2 is electrically connected to the first gate g1 of the first transistor T1. The second transistor T2 includes a second gate g2 and a second channel region b22. An orthographic projection of the second gate g2 on the substrate 1 and an orthographic projection of the second channel region b22 on the substrate 1 have a fourth overlapping portion Q4, and the fourth overlapping portion Q4 does not overlap with the first overlapping portion Q1.

An orthographic projection of the first channel region b11 of the first transistor T1 on the substrate 1 does not overlap with an orthographic projection of the second channel region b22 of the second transistor T2 on the substrate 1. The vertical projections of the first channel region b11 of the first transistor T1 and the second channel region b22 of the second transistor T2 on the substrate 1 are separated, with no overlapping area between them.

After the formation of the second transistor T2 film, subsequent inorganic and metal film formations typically exhibit wavy conformal topography. If the vertical projections of the first channel region b11 of the first transistor T1 and the second channel region b22 of the second transistor T2 on the substrate 1 overlap, it may easily cause unevenness at the channel of the top-layer first transistor T1, thereby affecting the performance characteristics of the first transistor.

In the embodiments of the present application, the vertical projections of the first channel region b11 of the first transistor T1 and the second channel region b22 of the second transistor T2 on the substrate 1 are separated, which is beneficial for the flatness of the channel of the first transistor T1, thereby ensuring the performance of the first transistor T1. In some embodiments, as shown in FIG. 1, the first transistor T1 includes a first active structure B1, and the first channel region b11 is located in the first active structure B1. The first active structure B1 includes the first channel region b11. The first plate c11 of the first capacitor Cst1 is disposed on a side of the first gate g1 away from the first active structure B1. The first transistor T1 has a bottom-gate structure. In this embodiment, it can be ensured that the first gate g1 can be reused as the second plate c24 of the first capacitor Cst1, and that three metal layers can form two capacitors, thereby saving the number of film layers.

Exemplarily, the first gate g1 of the first transistor T1 is electrically connected to the first electrode of the second transistor T2 through a first via h1, and the first via h1 is located outside the first overlapping portion formed by the orthographic projections of the first gate g1 of the first transistor T1 and the first channel region b11 on the substrate.

The first via h1 is located on a side of the first active structure B1 facing the substrate 1. In this embodiment, there is no spatial competition between the first via h1 and the first active structure B1. The first plate c11 of the first capacitor Cst1 is located directly below the first active structure B1, meaning that there is no spatial competition among the first via h1, the first capacitor Cst1, and the second capacitor Cst2, which can further maximize the plate areas of the first capacitor Cst1 and the second capacitor Cst2.

In some embodiments, as shown in FIG. 1, the second transistor T2 includes a second active structure B2 and a second gate g2 disposed in different layers. The second channel region b22 of the second transistor T2 is located in the second active structure B2. A first doped region b23 of the second active structure B2 is disposed on one side of the second channel region b22 and serves as the first electrode of the second transistor T2. A second doped region b24 of the second active structure B2 is disposed on a side of the second channel region b22 away from the first doped region b23 and serves as the second electrode of the second transistor T2. Exemplarily, the first doped region b23 is electrically connected to the first gate g1 of the first transistor T1 through the first via h1.

Exemplarily, in a direction parallel to the plane where the substrate 1 is located, the first via h1 is located on one side of the first plate c11 and the second plate c24. In the thickness direction Z of the array substrate, the first via h1 does not overlap with the first plate c11, and the first via h1 does not overlap with the second plate c24.

In some embodiments, as shown in FIG. 1, the pixel circuit further includes a second via h2. The array substrate further includes a plurality of first signal lines 31. The plurality of first signal lines 31 are disposed on a side of the second transistor T2 facing the first transistor T1. The second electrode of the second transistor T2 is electrically connected to a corresponding first signal line 31 through the second via h2. Exemplarily, the second doped region b24 is electrically connected to the corresponding first signal line 31 through the second via h2.

In the thickness direction Z of the array substrate, the first signal line 31 is located between the second transistor T2 and the first transistor T1. The first signal line 31 is electrically connected to the second electrode of the second transistor T2. The first signal line 31 is disposed between the second transistor T2 and the first transistor T1, which can prevent the depth of the second via h2 between the first signal line 31 and the second transistor T2 from being too deep.

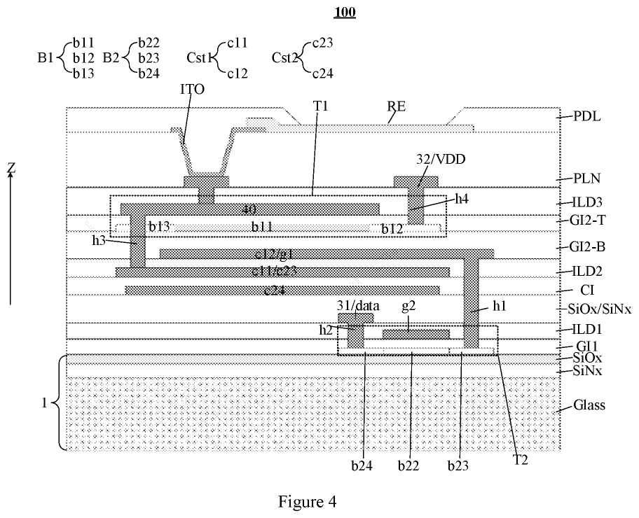

As an example, as shown in FIG. 1 or FIG. 4, the film layer where the plurality of first signal lines 31 are located is between the film layer where the second plate c24 of the second capacitor Cst2 is located and the film layer where the second gate g2 of the second transistor T2 is located. In this embodiment, the first signal line 31 and the second plate c24 are located in different metal layers. Thus, there is no spatial competition between the first signal line 31 and the second plate c24, which is beneficial for further increasing the plate area of the capacitor.

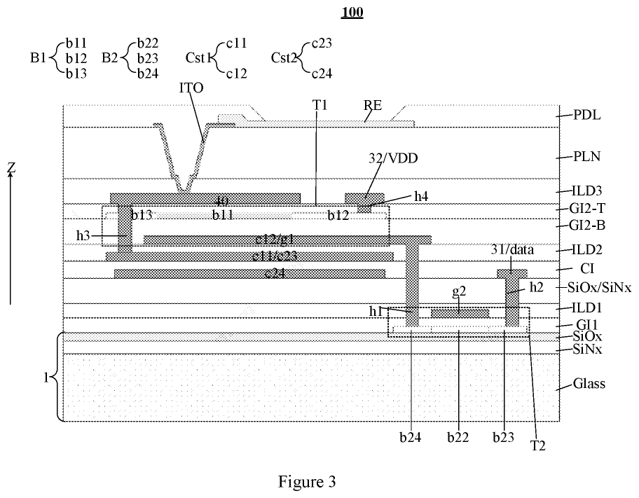

As another example, as shown in FIG. 3, the film layer where the plurality of first signal lines 31 are located is the same as the film layer where the second plate c24 of the second capacitor Cst2 is located, i.e., the film layer where the plurality of first signal lines 31 are located is the same film layer as the film layer where the second plate c24 of the second capacitor Cst2 is located. In this embodiment, the first signal line 31 and the second plate c24 are located in the same metal layer, which can reduce the number of film layers of the array substrate and simplify the fabrication flow of the array substrate. Compared with the structure shown in FIG. 1, the structure shown in FIG. 3 can reduce one Photo-Electro-Plating (PEP) process. The PEP processes corresponding to FIG. 1 and FIG. 3 will be exemplarily described below.

Exemplarily, as shown in FIG. 3, in the same pixel circuit, the second via h2 is located on a side of the first via h1 away from the second plate c24.

Exemplarily, the first signal line 31 includes a data signal line data.

In some embodiments, as shown in FIG. 1, the pixel circuit further includes a third via hole h3 and a fourth via hole h4, and the array substrate further includes a plurality of second signal lines 32, and: a first doped region b13 of the first active structure B1 and a second doped region b12 of the first active structure B1 are located on two sides of a first channel region b11, the first doped region b13 of the first active structure B1 serves as a first electrode of the first transistor T1, and the second doped region b12 of the first active structure B1 serves as a second electrode of the second transistor T2; the first electrode of the first transistor T1 is electrically connected to a first plate c11 of the first capacitor Cst1 through the third via hole h3, and the second electrode of the second transistor T2 is electrically connected to a corresponding second signal line 32 through the fourth via hole h4.

In this embodiment, the electrical connection between the first transistor T1 and the corresponding structure can be achieved through the third via hole h3 and the fourth via hole h4.

Exemplarily, the pixel circuit further includes a transfer portion 40, the transfer portion 40 is located on a side of the first active structure B1 away from the first gate g1, and the transfer portion 40 is electrically connected to the first electrode of the first transistor T1 and the first plate c11 of the first capacitor Cst1 through the third via hole h3.

The transfer portion 40 is located on a side of the first active structure B1 away from the substrate 1.

Exemplarily, the transfer portion 40 is electrically connected to a first electrode RE of a light-emitting element through a via hole.

Exemplarily, an orthographic projection of the transfer portion 40 on the substrate 1 covers an orthographic projection of the first channel region b11 on the substrate 1. In one embodiment, the transfer portion 40 can serve as a shielding function to improve the stability of the first transistor T1.

As an example, as shown in FIG. 1 and FIG. 3, the plurality of second signal lines 32 are in the same film layer as the transfer portion 40. The plurality of second signal lines 32 and the transfer portion 40 are in the same film layer. In this case, the inorganic film layer GI2T can be formed using a single film formation and double exposure etching process, respectively drilling holes to the first plate c11 and the first active structure B1 to stop, obtaining the third via hole h3 and the fourth via hole h4.

In one embodiment, as shown in FIG. 4, the film layer where the plurality of second signal lines 32 are located is on a side of the film layer where the transfer portion 40 is located away from the film layer where the first active structure B1 is located. In FIG. 4, the second signal line 32 is electrically connected to the first transistor T1 through the fourth via hole h4. The second signal line 32 and the transfer portion 40 are located in different metal layers, and there is no spatial competition between them, allowing for a more flexible arrangement of the second signal lines 32.

Exemplarily, the second signal line 32 includes a first power supply line VDD.

In some embodiments, the material of the first active structure B1 includes indium gallium zinc oxide, and the material of the second active structure B2 includes polysilicon.

The first transistor T1 is located on a side of the second transistor T2 away from the substrate 1.

The first signal line 31 is a data line, and the second signal line 32 is the first power supply line VDD.

The first transistor T1 is a driving transistor, and the second transistor T2 is a switching transistor.

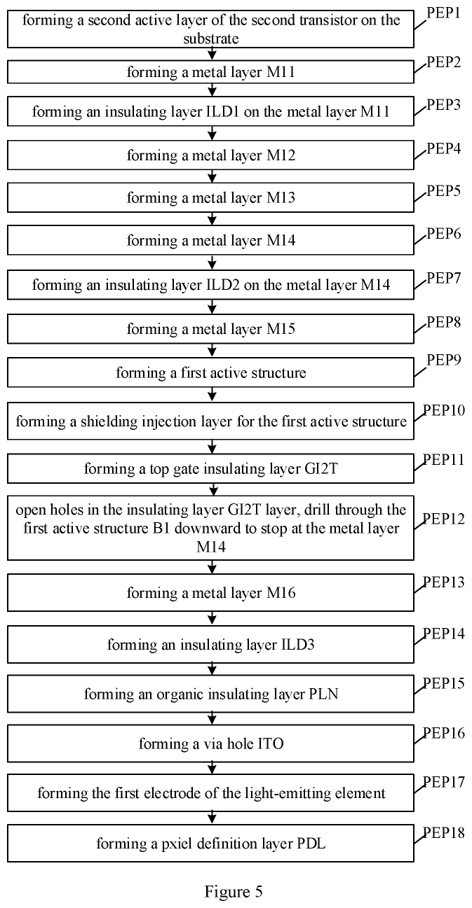

Exemplarily, the PEP process flow corresponding to the structure shown in FIG. 1 can be as shown in FIG. 5. In FIG. 5, the multiple metal layers sequentially away from the substrate 1 are respectively labeled as M11, M12, M13, M14, M15, M16.

Please refer to FIG. 1 and FIG. 5 in combination, the PEP process flows corresponding to the structure shown in FIG. 1 include PEP1 to PEP18:

PEP1: forming a second active layer of the second transistor T2 on the substrate 1, the second active layer including PSI. Here, taking the second transistor T2 as an LTPS transistor as an example, it can be an N-type or P-type device. After the second active layer of the second transistor T2 is completed, a first gate insulating layer GI1 is formed without patterning.

PEP2: forming a metal layer M11, the metal layer M11 serving as the metal layer where the second gate g2 of the second transistor T2 is located. The material of the metal layer M11 is Mo, Al, Cu metal, etc.

PEP3: forming an insulating layer ILD1 on the metal layer M11. Here, the insulating layer ILD1 is mainly an inorganic material, such as SiO2, SiNx, etc., and the insulating layer ILD1 is patterned and opened for upward connection of the metal layer M11 and the second active layer of the second transistor T2.

PEP4: forming a metal layer M12. The metal layer M12 serves as a signal routing layer for the first signal line 31 (data signal line data). The material of the metal layer M12 is Mo, Al, Cu metal, etc. After the metal layer M12 is completed, a SiOx/SiNx insulating layer is formed without patterning, and the material can be SiO2, SiNx, etc.

PEP5: forming a metal layer M13. The metal layer M13 serves as the film layer where the second plate c24 is located. The material of the metal layer M13 can be Mo, Al, Cu metal, etc. After the metal layer M13 is completed, an insulating layer CI is prepared without patterning. The material of the insulating layer CI can be SiO2, SiNx, etc.

PEP6: forming a metal layer M14. The metal layer M14 serves as a common metal plate layer for the first plate c11 and the first plate c23. The material of the metal layer M14 is Mo, Al, Cu metal, etc.

PEP7: forming an insulating layer ILD2 on the metal layer M14. The insulating layer ILD2 is mainly an inorganic material. In one embodiment of the present application, the insulating layer ILD2 is SiO2, SiNx, etc., and the insulating layer ILD2 is patterned and opened for upward connection of the second active layer of the second transistor T2 to the metal layer M15.

PEP8: forming a metal layer M15. The metal layer M15 serves as the metal layer where the gate g1 of the first transistor T1 is formed. The material of the metal layer M15 is Mo, Al, Cu metal, etc. After the metal layer M15 is completed, an insulating layer GI2B is prepared, and the insulating layer GI2B is not patterned. The material of the insulating layer GI2B can be SiO2, SiNx, etc. The insulating layer GI2B serves as a bottom gate insulating layer of the first transistor T1.

PEP9: Forming a first active structure B1. Here, taking the first transistor T1 as an oxide semiconductor (one type of IGZO) as an example, an N-type first transistor T1 is formed, and the first transistor T1 serves as a driving transistor. After the first active structure B1 is completed, an insulating layer GI2T for the top layer of the second gate is formed, and the insulating layer GI2T is not patterned.

PEP10: Forming a shielding injection layer SL for the first active structure B1 to achieve conductorization of the first active structure B1. The material of the shielding injection layer SL is a layer of PR photosensitive adhesive, which exists only during particle injection into the first active structure B1. After this process step is completed, a stripping operation is performed, and this layer of material is not present on the physical array substrate. Its size determines the channel length L of the first transistor T1.

PEP11: Forming a top gate insulating layer GI2T. The insulating layer GI2T may be made of SiO2 material. Patterning is performed to form via holes connecting the metal layer M16 and the first active structure B1, one of which is GI2T-1.

PEP12: Without performing separate film formation, continue to open holes in the insulating layer GI2T layer, drill through the first active structure B1 downward to stop at the metal layer M14, achieving a connection of the three layers M16-B1-M14 in a third via hole h3.

PEP13: Forming a metal layer M16. The metal layer M16 serves as the metal layer where the transfer portion 40 and the second signal line 32 are located. The material of the metal layer M16 may be Mo, Al, Cu metals, etc.

PEP14: Forming an insulating layer ILD3. Here, the insulating layer ILD3 is mainly composed of inorganic materials. In one embodiment of the present application, the insulating layer ILD3 is SiO2, SiNx, etc., and the insulating layer ILD3 is patterned to open holes for subsequent upward connections.

PEP15: Forming an organic insulating layer PLN. Here, the insulating layer PLN is mainly composed of organic materials, such as polyimide, and the insulating layer PLN is patterned to open holes for subsequent upward connections.

PEP16: Forming a via hole ITO. The via hole ITO connects the first electrode of the light-emitting element and the transfer portion 40.

PEP17: Forming the first electrode of the light-emitting element. In one embodiment of the present application, the first electrode of the light-emitting element is an anode RE, and the material of the anode RE is an ITO/Ag/ITO three-layer material.

PEP18: Forming a pixel definition layer PDL. The pixel definition layer PDL may be an organic material. In one embodiment of the present application, the pixel definition layer PDL is polyimide.

The above is an introduction to the PEP process flow corresponding to the structure shown in FIG. 1.

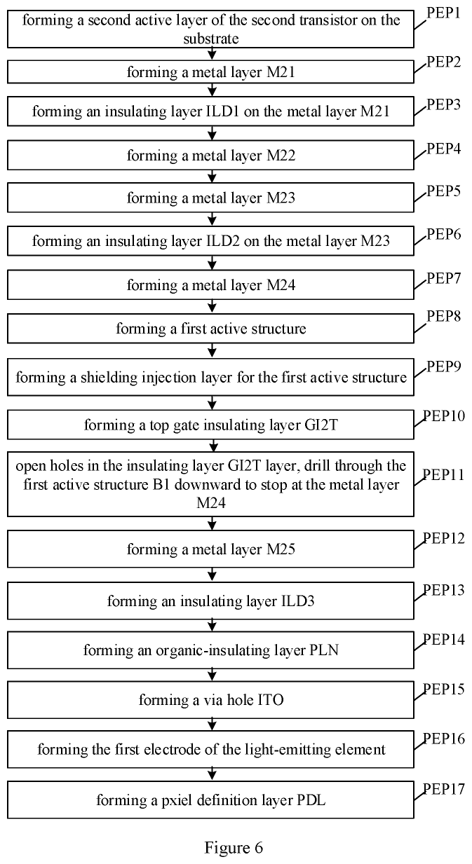

FIG. 6 is the PEP process flow corresponding to the structure shown in FIG. 3.

In FIGS. 3 and 6, the multiple metal layers sequentially away from the substrate 1 are respectively labeled as M21, M22, M23, M24, M25.

The similarities between FIG. 6 and FIG. 5 are not repeated here, and the differences include: the first signal line 31 and the second electrode plate c24 are located on the same metal layer, simplifying the PEP process flow to PEP17.

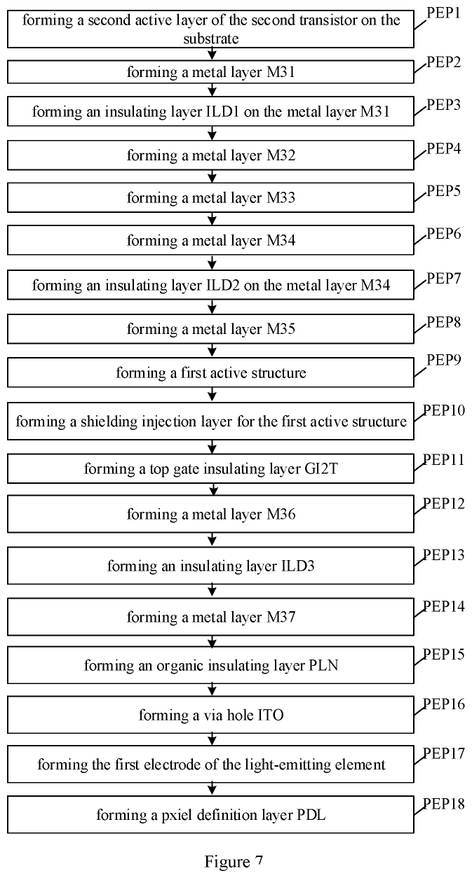

FIG. 7 is the PEP process flow corresponding to the structure shown in FIG. 4.

In FIGS. 4 and 7, the multiple metal layers sequentially away from the substrate 1 are respectively labeled as M31, M32, M33, M34, M35, M36, M37.

The similarities between FIG. 7 and FIG. 5 are not repeated here, and the differences include: the second signal line 32 and the transfer portion 40 are located on different metal layers, the second signal line 32 is connected to the first active structure B1 of the first transistor T1 through a fourth via hole h4, and the PEP process flow maintains PEP18.

In some embodiments, please refer to FIGS. 1, 13, and 14 in combination. Multiple pixel circuits are arranged along a first direction X and a second direction Y, and: multiple first gates g1 of the multiple pixel circuits are spaced apart from each other, the first gates g1 extend along the second direction Y, multiple second gates g2 of the multiple pixel circuits arranged along the first direction X have an integral structure, and multiple second gates g2 of the multiple pixel circuits arranged along the second direction Y are spaced apart from each other.

The first gate g1 and the second electrode plate c12 of the first capacitor Cst1 are shared. Multiple second electrode plates c12 of the multiple pixel circuits are spaced apart from each other. The first gate g1 is the gate of the first transistor T1, and the first transistor T1 can serve as a driving transistor of the pixel circuit. The multiple first gates g1 are spaced apart from each other, which can avoid mutual interference among the multiple first gates g1, thereby ensuring the accuracy of the gate potential of the first transistor T1 in different pixel circuits.

The second gate g2 and the scan line Scan have an integral structure. The second gate g2 is the gate of the second transistor T2, and the second transistor T2 is a switching transistor of the pixel circuit. The first direction X may be the row direction. The second gates g2 of the second transistors T2 in multiple pixel circuits in the same row have an integral structure, allowing the state of multiple second transistors T2 to be controlled simultaneously based on one scan line.

Exemplarily, as shown in FIG. 12, the first electrode plates c11 of the first capacitors Cst1 of the multiple pixel circuits are spaced apart from each other, and the first electrode plates c11 of the first capacitors Cst1 extend along the second direction Y.

Exemplarily, as shown in FIG. 1, the orthographic projection of the first gate g1 on the substrate 1 includes a first portion P1, the first portion P1 is located outside the orthographic projection of the corresponding first electrode plate c11 of the first capacitor Cst1 on the substrate 1, the orthographic projection of the first electrode plate c11 of the first capacitor Cst1 on the substrate 1 includes a second portion P2, and the second portion P2 is located outside the orthographic projection of the corresponding first gate g1 on the substrate 1.

The second electrode plate c12 of the first capacitor Cst1 and the first gate g1 are shared. In this embodiment, the first electrode plate c11 and the second electrode plate c12 of the first capacitor Cst1 have portions that are staggered from each other, which can reserve space for connecting the first via hole h1 and the third via hole h3.

Exemplarily, the first gate g1 extends along the second direction Y, the first electrode plate c11 and the second electrode plate c12 of the first capacitor Cst1 extend along the second direction Y, and the corresponding first portion P1, first overlapping portion Q1, and second portion P2 are arranged along the second direction Y.

Exemplarily, as shown in FIG. 12, the second electrode plates c24 of the plurality of second capacitors Cst2 of the plurality of pixel circuits arranged along the first direction X are of an integral structure, and the second electrode plates c24 of the plurality of second capacitors Cst2 of the plurality of pixel circuits arranged along the second direction Y are spaced apart from each other.

The second electrode plate c24 of the second capacitor Cst2 is configured to be connected to a fixed voltage. In the case where the second electrode plates c24 of the plurality of second capacitors Cst2 of the plurality of pixel circuits arranged along the first direction X are of an integral structure, it is convenient to connect the same signal to the second electrode plates c24 of the plurality of second capacitors Cst2.

Exemplarily, as shown in FIG. 10, the array substrate further includes a plurality of first signal lines 31, the first signal lines 31 extend along the second direction Y, the second electrodes of the plurality of second transistors T2 of the plurality of pixel circuits arranged along the second direction Y are electrically connected to the same first signal line 31, and the second electrodes of the plurality of second transistors T2 of the plurality of pixel circuits arranged along the first direction X are electrically connected to different first signal lines 31.

Exemplarily, the second direction Y is a column direction, and one column of pixel circuits is correspondingly provided with one first signal line 31.

Exemplarily, as shown in FIG. 16, the array substrate further includes a plurality of second signal lines 32, the second signal lines 32 extend along the first direction X, the second electrodes of the plurality of first transistors of the plurality of pixel circuits arranged along the first direction X are electrically connected to the same second signal line 32, and the second electrodes of the plurality of first transistors of the plurality of pixel circuits arranged along the second direction Y are electrically connected to different second signal lines 32.

Exemplarily, the first direction X is a row direction, and one row of pixel circuits is correspondingly provided with one second signal line 32.

Exemplarily, as shown in FIG. 16, the pixel circuit further includes a transfer portion 40, the transfer portion 40 is electrically connected to the first electrode of the first transistor, the plurality of transfer portions 40 of the plurality of pixel circuits are spaced apart from each other, and the transfer portion 40 extends along the second direction Y.

In some embodiments, referring to FIG. 1, FIG. 14, and FIG. 15, the array substrate further includes a plurality of first electrodes RE, the first electrodes RE are located on a side of the plurality of pixel circuits away from the substrate 1, and the orthographic projection of the first electrode RE on the substrate 1 overlaps with the first overlapping portion Q1. Thus, the transfer portion 40 can provide a shielding effect to improve the stability of the first transistor T1.

Exemplarily, the first overlapping portion Q1 is located within the orthographic projection of the first electrode RE on the substrate. Thus, the first electrode RE can better shield the influence of light on the first transistor T1.

Exemplarily, as shown in FIG. 1, the orthographic projection of the second electrode plate c12 on the substrate 1 surrounds the orthographic projection of the first channel region b11 on the substrate 1.

The area of the second electrode plate c12 is larger than the area of the first channel region b11, and the orthographic projection of the first channel region b11 on the substrate 1 falls within the orthographic projection of the second electrode plate c12 on the substrate 1.

Exemplarily, in the thickness direction Z of the array substrate, there is no metal layer between the second electrode plate c12 and the first active structure B1, and the second electrode plate c12 and the first active structure B1 include an inorganic film layer GI2-B, which is an insulating layer.

Exemplarily, no via hole appears between the first channel region b11 and the second electrode plate c12. The depth of an inorganic via hole is usually large and the via hole is steep. If the effective channel of an oxide transistor falls into the hole, abnormal characteristics of the oxide transistor may occur.

In the embodiment of the present application, since the orthographic projection of the second electrode plate c12 on the substrate 1 surrounds the orthographic projection of the first channel region b11 on the substrate 1, it can be ensured that there is a whole piece of metal and a continuous inorganic film layer without fracture under the first channel region b11, avoiding the boundary of a metal or inorganic via hole under the first channel region b11, thereby further ensuring that the channel region of the first transistor T1 can be flat, thus better ensuring the characteristics of the first transistor T1.

Exemplarily, the orthographic projection of the first electrode plate c11 on the substrate 1 surrounds the orthographic projection of the first channel region b11 on the substrate 1. The first electrode plate c11 and the first electrode plate c23 are the same electrode plate, that is, the orthographic projection of the first electrode plate c23 on the substrate 1 surrounds the orthographic projection of the first channel region b11 on the substrate 1.

Exemplarily, the orthographic projection of the second electrode plate c24 on the substrate 1 surrounds the orthographic projection of the first channel region b11 on the substrate 1.

The orthographic projections of the first electrode plate c11, the second electrode plate c12, and the second electrode plate c24 on the substrate 1 overlap. Thus, providing two capacitors in the same planar area can further reduce the planar area occupied by the two capacitors, thereby further improving the PPI.

Exemplarily, an alternating current signal is transmitted on the scan line Scan. In one embodiment of the present application, a signal alternating between a high level and a low level is transmitted on the scan line Scan. When the scan line Scan is at a low level, the second transistor T2 is turned on; when the scan line Scan is at a high level, the second transistor T2 is turned off.

In the thickness direction of the array substrate, the second electrode plate c24 is located between the second gate g2 of the second transistor T2 and the first electrode plate c11. When the second electrode plate c24 is connected to a direct current signal, the second electrode plate c24 can provide a shielding effect to reduce the coupling influence of the voltage jump of the second gate g2 on the potential of the first electrode plate c11, thereby stabilizing the potential of the first electrode plate c11.

Exemplarily, the first electrode plate c11 is electrically connected to the first electrode of the light-emitting element D. The second electrode plate c24 can provide a shielding effect to reduce the coupling influence of the voltage jump of the second gate g2 on the potential of the first electrode of the light-emitting element, thereby improving the stability of the light emission brightness.

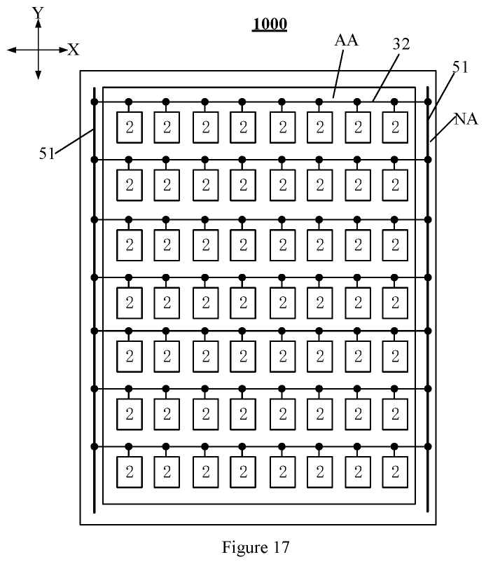

Based on the same technical concept, an embodiment of the present application also provides a display panel. As shown in FIG. 17, the display panel includes a display area AA and a border area NA, and the display panel includes a first power supply line 51 and the array substrate according to any one of the above embodiments.

The first power supply line 51 is at least located in the border area NA, and the first power supply line 51 is configured to supply a first power supply voltage.

The plurality of pixel circuits 2 are located in the display area AA and arranged along the first direction X and the second direction Y. The array substrate further includes a plurality of second signal lines 32, the second signal lines 32 are electrically connected to the second electrodes of the corresponding first transistors, and the second signal lines 32 extend along the first direction X and are electrically connected to the first power supply line 51 in the border area NA.

A plurality of second signal lines 32 are arranged along the second direction Y. Exemplarily, the array substrate includes a display area and a non-display area, and in the first direction, power supply buses are disposed in the non-display areas on both sides of the display area, and the second signal lines 32 are electrically connected to the power supply buses.

Exemplarily, the second electrode plates c24 of different pixel circuits 2 arranged along the first direction X are of an integral structure. That is, the second electrode plates c24 of a plurality of pixel circuits 2 arranged along the first direction X are connected as one piece.

Exemplarily, the second electrode plate c24 and the second signal line 32 are electrically connected to a border area of the array substrate through via holes.

The display panel provided in the present application may be an organic light-emitting diode (OLED) display panel.

It should be understood that in other implementations of the present application, the display panel may also be a micro light-emitting diode (Micro LED) display panel, a quantum dot display panel, or the like.

The display panel provided in the embodiments of the present application has the beneficial effects of the array substrate provided in the embodiments of the present application. For details, reference may be made to the specific description of the array substrate in the above embodiments, which will not be repeated here in this embodiment.

In some embodiments, as shown in FIG. 1, the pixel circuit further includes a second transistor T2 and a second capacitor Cst2.

The second transistor T2 is disposed on a side of the first capacitor Cst1 away from the first transistor T1, and a first electrode of the second transistor T2 is electrically connected to a first gate electrode g1 of the first transistor T1. In the thickness direction Z of the array substrate, the second transistor T2 is located on a side of the first capacitor Cst1 away from the first transistor T1.

A first electrode plate c11 of the first capacitor Cst1 serves as a first electrode plate c23 of the second capacitor Cst2, a second electrode plate c24 of the second capacitor Cst2 is disposed between the second transistor T2 and the first electrode plate c11 of the first capacitor Cst1, and the second electrode plate c24 of the second capacitor Cst2 is configured to receive a fixed voltage.

In one embodiment, as shown in FIG. 12, the second electrode plates c24 of a plurality of second capacitors Cst2 of a plurality of pixel circuits arranged along the first direction X are of an integral structure and are electrically connected to corresponding signal lines in the border area. The second electrode plates c24 of a plurality of second capacitors Cst2 of a plurality of pixel circuits arranged along the second direction Y are spaced apart from each other.

Exemplarily, with reference to FIG. 12 and FIG. 17, the second electrode plates c24 of a plurality of second capacitors Cst2 of a plurality of pixel circuits arranged along the first direction X are of an integral structure and are electrically connected to a first power supply line 51 in the border area.

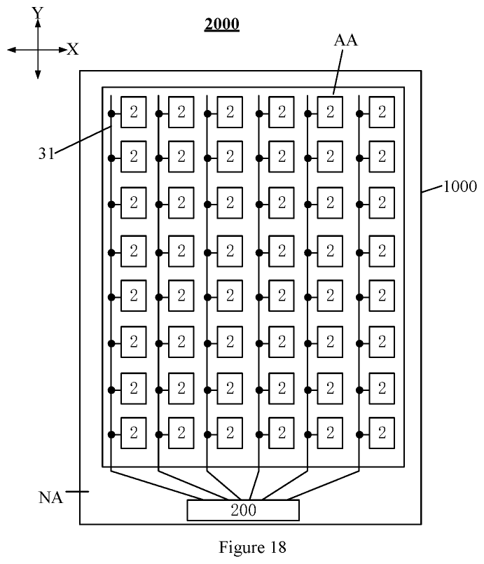

Based on the same technical concept, an embodiment of the present application further provides a display device. As shown in FIG. 18, the display device 2000 includes a driving chip 200 and a display panel 1000.

The driving chip 200 is used to provide a data voltage.

The display panel 1000 includes the display panel according to any one of the above embodiments.

In one embodiment, with reference to FIG. 1 and FIG. 18, the pixel circuit further includes a second transistor T2, the second transistor T2 is disposed on a side of the first capacitor Cst1 away from the first transistor T1, a first electrode of the second transistor T2 is electrically connected to the first gate electrode g1, the array substrate further includes a plurality of first signal lines 31, the first signal lines 31 extend along the second direction Y and are electrically connected to the driving chip 200 in the border area NA, and the first signal lines 31 are electrically connected to a second electrode of the corresponding second transistor T2.

The display device provided in the embodiments of the present application has the beneficial effects of the array substrate provided in the embodiments of the present application. For details, reference may be made to the specific description of the array substrate in the above embodiments, which will not be repeated here in this embodiment.

The transistors in the embodiments of the present application may be N-type transistors or P-type transistors. For an N-type transistor, the turn-on level is a high level, and the turn-off level is a low level. That is, when the gate potential of the N-type transistor is at a high level, the first electrode and the second electrode thereof are turned on, and when the gate potential of the N-type transistor is at a low level, the first electrode and the second electrode thereof are turned off. For a P-type transistor, the turn-on level is a low level, and the turn-off level is a high level. That is, when the gate potential of the P-type transistor is at a low level, the first electrode and the second electrode thereof are turned on, and when the gate potential of the P-type transistor is at a high level, the first electrode and the second electrode thereof are turned off. In specific implementation, the gate of each of the above transistors serves as its control electrode, and depending on the signal of the gate of each transistor and its type, its first electrode may be used as a source electrode and the second electrode as a drain electrode, or its first electrode may be used as a drain electrode and the second electrode as a source electrode, which is not distinguished here. In addition, the turn-on level and turn-off level in the embodiments of the present application are general terms; the turn-on level refers to any level that can turn on the transistor, and the turn-off level refers to any level that can turn off/disable the transistor.

The embodiment of FIG. 18 only takes a mobile phone as an example to describe the display device 2000. It is understandable that the display device provided in the embodiments of the present application may be a wearable product, a computer, a television, a vehicle-mounted display device, or other display devices with display functions, and the present application is not particularly limited thereto. The display device provided in the embodiments of the present application has the beneficial effects of the display panel provided in the embodiments of the present application. For details, reference may be made to the specific description of the display panel in the above embodiments, which will not be repeated here in this embodiment.

According to the embodiments of the present application as described above, these embodiments do not exhaust all details, nor do they limit the application to the specific embodiments described. Obviously, many modifications and variations can be made based on the above description. This specification selects and specifically describes these embodiments to better explain the principles and practical applications of the present application, so that those skilled in the art can make good use of the present application and modifications based on the present application. The present application is limited only by the claims and their full scope and equivalents.

What is claimed is:

1. An array substrate, comprising a substrate and a plurality of pixel circuits disposed on one side of the substrate, wherein a pixel circuit of the plurality of pixel circuits comprises:
a first transistor, comprising a first gate and a first channel region; and
a first capacitor, wherein a first plate of the first capacitor is disposed on one side of the first transistor and electrically connected to a first electrode of the first transistor, and the first gate serves as a second plate of the first capacitor;
wherein an orthographic projection of the first gate on the substrate and an orthographic projection of the first channel region on the substrate have a first overlapping portion, an orthographic projection of the first plate of the first capacitor on the substrate and an orthographic projection of the second plate of the first capacitor on the substrate have a second overlapping portion, and the first overlapping portion and the second overlapping portion overlap.

2. The array substrate according to claim 1, wherein the pixel circuit further comprises:
a second transistor, disposed on a side of the first capacitor away from the first transistor, wherein a first electrode of the second transistor is electrically connected to the first gate;
a second capacitor, wherein the first plate of the first capacitor serves as a first plate of the second capacitor, a second plate of the second capacitor is disposed between the second transistor and the first plate of the first capacitor, and the second plate of the second capacitor is configured to receive a fixed voltage.

3. The array substrate according to claim 2, wherein an orthographic projection of the first plate of the second capacitor on the substrate and an orthographic projection of the second plate of the second capacitor on the substrate have a third overlapping portion, and the third overlapping portion and the first overlapping portion overlap;
the first overlapping portion is located within the third overlapping portion, and the first overlapping portion is located within the second overlapping portion.

4. The array substrate according to claim 2, wherein the second transistor comprises a second gate and a second channel region, an orthographic projection of the second gate on the substrate and an orthographic projection of the second channel region on the substrate have a fourth overlapping portion, wherein the fourth overlapping portion overlaps with the second overlapping portion, and the fourth overlapping portion overlaps with the third overlapping portion.

5. The array substrate according to claim 1, wherein:
the first overlapping portion is located within the second overlapping portion;
the pixel circuit further comprises a second transistor, disposed on a side of the first capacitor away from the first transistor, a first electrode of the second transistor is electrically connected to the first gate, the second transistor comprises a second gate and a second channel region, an orthographic projection of the second gate on the substrate and an orthographic projection of the second channel region on the substrate have a fourth overlapping portion, and the fourth overlapping portion and the first overlapping portion do not overlap.

6. The array substrate according to claim 2, wherein the first transistor comprises a first active structure, the first channel region is located in the first active structure,
the first plate of the first capacitor is disposed on a side of the first gate away from the first active structure.

7. The array substrate according to claim 6, wherein the pixel circuit further comprises a first via hole, the first electrode of the second transistor is electrically connected to the first gate through the first via hole, and an orthographic projection of the first via hole on the substrate is located outside the first overlapping portion.

8. The array substrate according to claim 6, wherein the second transistor comprises a second active structure and a second gate disposed in different layers, a second channel region of the second transistor is located in the second active structure, a first doped region of the second active structure is disposed on one side of the second channel region and serves as the first electrode of the second transistor, and a second doped region of the second active structure is disposed on a side of the second channel region away from the first doped region and serves as a second electrode of the second transistor.

9. The array substrate according to claim 2, wherein the pixel circuit further comprises a second via hole, the array substrate further comprises:
a plurality of first signal lines, the plurality of first signal lines are disposed on a side of the second transistor facing the first transistor, and a second electrode of the second transistor is electrically connected to a corresponding first signal line through the second via hole;
a film layer where the plurality of first signal lines are located is between a film layer where the second plate of the second capacitor is located and a film layer where the second gate of the second transistor is located, or the film layer where the plurality of first signal lines are located is the same film layer as the film layer where the second plate of the second capacitor is located.

10. The array substrate according to claim 6, wherein the pixel circuit further comprises a third via hole and a fourth via hole, the array substrate further comprises a plurality of second signal lines, wherein a first doped region of the first active structure and a second doped region of the first active structure are located on two sides of the first channel region, the first doped region of the first active structure serves as the first electrode of the first transistor, and the second doped region of the first active structure serves as a second electrode of the first transistor;
the first electrode of the first transistor is electrically connected to the first plate of the first capacitor through the third via hole, and the second electrode of the first transistor is electrically connected to a corresponding second signal line through the fourth via hole.

11. The array substrate according to claim 10, wherein one of the pixel circuits further comprises a transfer portion, the transfer portion is located on a side of the first active structure away from the first gate, the transfer portion is electrically connected to the first electrode of the first transistor and the first plate of the first capacitor through the third via hole; a film layer where the plurality of second signal lines are located is the same film layer as a film layer where the transfer portion is located, or the film layer where the plurality of second signal lines are located is on a side of the film layer where the transfer portion is located away from the film layer where the first active structure is located.

12. The array substrate according to claim 6, wherein a material of the first active structure comprises indium gallium zinc oxide, and a material of the second active structure comprises polysilicon; the first transistor is located on a side of the second transistor away from the substrate; the first signal line is a data line, and the second signal line is a first power supply line; the first transistor is a driving transistor, and the second transistor is a switching transistor.

13. The array substrate according to claim 6, wherein the plurality of pixel circuits are arranged along a first direction and a second direction, wherein: the plurality of first gates of the plurality of pixel circuits are spaced apart from each other, the first gates extend along the second direction, the plurality of second gates of the plurality of pixel circuits arranged along the first direction are of an integral structure, and the plurality of second gates of the plurality of pixel circuits arranged along the second direction are spaced apart from each other; the first plates of the plurality of first capacitors of the plurality of pixel circuits are spaced apart from each other, and the first plates of the first capacitors extend along the second direction.

14. The array substrate according to claim 13, wherein an orthographic projection of the first gate on the substrate comprises a first portion, the first portion is located outside an orthographic projection of the corresponding first plate of the first capacitor on the substrate, and the orthographic projection of the first plate of the first capacitor on the substrate comprises a second portion, the second portion is located outside the orthographic projection of the corresponding first gate on the substrate; the corresponding first portion, the first overlapping portion, and the second portion are arranged along the second direction.

15. The array substrate according to claim 13, wherein second plates of the plurality of second capacitors of the plurality of pixel circuits arranged along the first direction are of an integral structure, and second plates of the plurality of second capacitors of the plurality of pixel circuits arranged along the second direction are spaced apart from each other; the array substrate further comprises a plurality of first signal lines, the first signal lines extend along the second direction, second electrodes of the plurality of second transistors of the plurality of pixel circuits arranged along the second direction are electrically connected to the same first signal line, and second electrodes of the plurality of second transistors of the plurality of pixel circuits arranged along the first direction are electrically connected to different first signal lines.

16. The array substrate according to claim 13, wherein the array substrate further comprises a plurality of second signal lines, the plurality of second signal lines respectively extend along the first direction, second electrodes of the plurality of first transistors of the plurality of pixel circuits arranged along the first direction are electrically connected to the same second signal line, and second electrodes of the plurality of first transistors of the plurality of pixel circuits arranged along the second direction are electrically connected to different second signal lines; the plurality of pixel circuits further comprise a plurality of transfer portions, at least one transfer portion of one of the pixel circuits is electrically connected to the first electrode of the first transistor, the plurality of transfer portions of the plurality of pixel circuits are spaced apart from each other, and the plurality of transfer portions respectively extend along the second direction.

17. The array substrate according to claim 8, wherein the array substrate further comprises: a plurality of first electrodes, located on a side of the plurality of pixel circuits away from the substrate, an orthographic projection of the first electrode on the substrate overlaps with the first overlapping portion; the first overlapping portion is located within the orthographic projection of the first electrode on the substrate.

18. A display panel, comprising a display area and a border area, the display panel comprising:
a first power supply line, at least located in the border area and configured to supply a first power supply voltage; and
the array substrate according to claim 1, the plurality of pixel circuits are located in the display area and arranged along a first direction and a second direction, the array substrate further comprises a plurality of second signal lines, the second signal lines are electrically connected to the second electrodes of the corresponding first transistors, the second signal lines extend along the first direction and are electrically connected to the first power supply line in the border area.

19. The display panel according to claim 18, wherein one of the pixel circuits further comprises:
a second transistor, disposed on a side of the first capacitor away from the first transistor, a first electrode of the second transistor is electrically connected to the first gate;
a second capacitor, the first plate of the first capacitor serves as a first plate of the second capacitor, a second plate of the second capacitor is disposed between the second transistor and the first plate of the first capacitor, and the second plate of the second capacitor is configured to supply a fixed voltage;
wherein second plates of the plurality of second capacitors of the plurality of pixel circuits arranged along the first direction are of an integral structure and are electrically connected to a corresponding signal line in the border area, and second plates of the plurality of second capacitors of the plurality of pixel circuits arranged along the second direction are spaced apart from each other;
the second plates of the plurality of second capacitors of the plurality of pixel circuits arranged along the first direction are of an integral structure and are electrically connected to the first power supply line in the border area.

20. A display device, comprising: a driving chip, configured to supply a data voltage;
and the display panel according to claim 18; wherein the pixel circuit further comprises a second transistor, disposed on a side of the first capacitor away from the first transistor, a first electrode of the second transistor is electrically connected to the first gate, the array substrate further comprises a plurality of first signal lines, the first signal lines extend along the second direction and are electrically connected to the driving chip in the border area, and the first signal lines are electrically connected to the second electrodes of the corresponding second transistors.
